(19) United States
(12) Patent Application Publication
(10) Pub. No.: US 2026/0295764 A1
(43) Pub. Date: Oct. 1, 2026

(54) CHEMICAL MECHANICAL POLISHING SYSTEM AND CONTROLLING METHOD THEREOF

(71) Applicants: SK hynix Inc., Icheon-si Gyeonggi-do (KR); Korea University Research and Business Foundation, Sejong Campus, Sejong-si (KR)

(72) Inventors: JUN HO JANG, Icheon-si Gyeonggi-do (KR); JAE WOO LEE, Sejong-si (KR)

(73) Assignees: SK hynix Inc., Icheon-si Gyeonggi-do (KR); Korea University Research and Business Foundation, Sejong Campus, Sejong-si (KR)

(21) Appl. No.: 19/576,243

(22) Filed: Mar. 24, 2026

(30) Foreign Application Priority Data
Mar. 25, 2025 (KR) 10-2025-0038237

(51) Int. Cl. B24B 37/005; B24B 37/32; H10P 52/40

(52) U.S. Cl. CPC B24B 37/005; B24B 37/32; H10P 52/40

(57) ABSTRACT

A chemical mechanical polishing (CMP) device for wafers includes: a platen and a polishing pad on a first surface of the platen; a head that rotates and vibrates the wafer; a retainer ring disposed at an edge of the polishing pad and configured to prevent the wafer from dislodging from the head; and a control unit configured to calculate a movement trajectory of at least one reference point on a surface of the retainer ring in contact with the polishing pad and a center point of the retainer ring; calculate a sliding distance of the at least one reference point and a trajectory distribution density of the movement trajectory of the center point; predict a wear profile of the retainer ring; and control process conditions of the CMP process based on the wear profile.

### CROSS-REFERENCE TO RELATED APPLICATION

The present application claims priority under 35 U.S.C. § 119 (a) to Korean Patent Application No. 10-2025-0038237, filed in the Korean Intellectual Property Office on Mar. 25, 2025, the entire contents of which application is incorporated herein by reference.

### BACKGROUND

### 1. Technical Field

The present disclosure relates to a chemical mechanical polishing device and a control method of control of the chemical mechanical polishing device, including but not limited to a chemical mechanical polishing device and a method of control of the chemical mechanical polishing device for a semiconductor wafer.

### 2. Related Art

Today, the growing demand for increasing the integration of semiconductor devices utilized multilayer process technology for the manufacture of highly integrated semiconductor devices, such as 3D semiconductor devices, for example. As process technology for multilayer interconnection and precision circuit patterning, planarization technology using uniform removal of various thin layers formed on semiconductor wafers, for example, conductive layers such as metal layers for wiring, semiconductor layers such as silicon, dielectric layers, or insulating layers, is becoming increasingly important.

One planarization technology, Chemical Mechanical Polishing (CMP) process is a planarization method that simultaneously utilizes a mechanical method using a polishing pad and an abrasive, and a chemical method of etching a thin film on a wafer by a chemical composition in a slurry solution to obtain selectivity of the etched layer. Typically, such a CMP process includes placing a polishing pad on the upper surface of a platen, rotating the platen to rotate the polishing pad, and supplying an abrasive slurry to a predetermined area on the upper surface of the polishing pad. A rotatable and oscillatable wafer carrier or head is arranged on the upper surface of the polishing pad, and a wafer held by the head is rotated and oscillated in close contact with the surface of the polishing pad such that the surface of the wafer is leveled by the frictional effects.

The head is coupled to a retainer ring. The retainer ring serves as a guide that, while the wafer is chemically and mechanically polished, holds the edge of the wafer in direct contact with the polishing pad, preventing the wafer from being dislodged from the head by frictional forces generated between the polishing pad and the wafer as the wafer rotates.

Because the retainer ring is in direct contact with the polishing pads and slurry during the CMP process, the retainer ring will wear out and gradually become thinner and undergoes a wear profile or a change in profile, such as galling. The wear profile of the retainer ring affects the outermost polishing rate of the wafer surface, which may have a significant impact on the productivity and quality of highly integrated semiconductor devices such as 3D devices. The wear of the retainer rings also affects process efficiency, including process throughput, as the wear is related to the frequency of their replacement.

### SUMMARY

In an embodiment including a chemical mechanical polishing (CMP) device for a wafer from which semiconductor devices are formed, the CMP device may include: a platen and a polishing pad disposed on a first surface of the platen in a configuration that performs a CMP process on a wafer; a head that rotates and vibrates the wafer on the polishing pad; a retainer ring disposed at an edge of the polishing pad and configured to prevent the wafer from dislodging from the head during the CMP process; and a control unit configured to: calculate a movement trajectory on the polishing pad of at least one reference point on a surface of the retainer ring in contact with the polishing pad and a center point of the retainer ring during the CMP process; calculate a sliding distance of the at least one reference point and a trajectory distribution density of the movement trajectory of the center point; predict a wear profile of the retainer ring based on the sliding distance and the trajectory distribution density; and control process conditions of the CMP process based on the wear profile.

In an embodiment, a method of controlling a chemical mechanical polishing (CMP) process that polishes a wafer from which semiconductor devices are formed may include: using a head, rotating and vibrating the wafer on a polishing pad disposed on a first surface of a platen while a retainer ring disposed at an edge of the wafer prevents separation of the wafer from the head during the CMP process; calculating, during the CMP process, a movement trajectory on the polishing pad of at least one reference point on a surface of the retainer ring contacting the polishing pad and a center point of the retainer ring, and calculating a sliding distance of the reference point and a trajectory distribution density of the movement trajectory of the center point; predicting a wear profile of the retainer ring based on the sliding distance and the trajectory distribution density; and controlling process conditions of the CMP process based on the wear profile.

In an embodiment, a method of modeling a wear profile of a retainer ring for a CMP process, the method may include calculating, during a CMP process, a movement trajectory on a polishing pad of at least one reference point on a surface of the retainer ring contacting the polishing pad and a center point of the retainer ring and calculating a sliding distance of the reference point and a trajectory distribution density of the movement trajectory of the center point; and predicting a wear profile of the retainer ring based on the sliding distance and the trajectory distribution density.

### BRIEF DESCRIPTION OF THE DRAWINGS

FIG. 1A illustrates a CMP apparatus according to an embodiment of the present disclosure, and FIG. 1B illustrates the movement of a retainer ring, a wafer, and a polishing pad during the CMP process according to an embodiment of the present disclosure.

FIG. 2 is a flowchart illustrating a method of control of chemical mechanical polishing of a wafer according to an embodiment of the present disclosure.

FIG. 3 illustrates movement trajectory of a reference point and a center point of a retainer ring with horizontal linear vibration in accordance with an embodiment of the present disclosure.

FIG. 4 illustrates a method of calculating movement trajectory of a retainer ring undergoing longitudinal arc oscillation according to an embodiment of the present disclosure.

FIG. 5a to FIG. 51 show the calculated result of the movement trajectory of the retainer ring over time of a CMP process according to an embodiment of the present disclosure.

FIG. 6a and FIG. 6b illustrate the movement trajectory of a predetermined reference point of the retainer ring according to an embodiment of the present disclosure.

FIG. 7 illustrates movement trajectories of a plurality of reference points on a retainer ring in accordance with an embodiment of the present disclosure.

FIG. 8 shows calculated results of sliding distance ratio of the outer region to the inner region of the retainer ring for different rotational speed ratios of the polishing pad and head of the CMP process according to an embodiment of the present disclosure.

FIG. 9 shows a distribution of the movement trajectory of the retainer ring according to two types of vibration of the retainer ring according to an embodiment of the present disclosure.

FIG. 10 shows the measurement locations of the outer thickness and the inner thickness of the retainer ring to evaluate conformity between the simulation results of the wear profile prediction of the retainer ring according to an embodiment of the present disclosure.

FIG. 11 is a graph showing the measured results of the wear ratio of the outer and inner surfaces of the retainer ring along the vibration path of the retainer ring caused by the actual CMP process according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be referred to as a second element in one example, and the second element may be referred to as a first element in another example.

When one element is identified as “coupled” to another element, the elements may be coupled directly or through at least one intervening element between the elements. When two elements are identified as “directly coupled,” one element is directly coupled to the other element without an intervening element between the two elements.

The terms “about,” “substantially,” and the like as used in the disclosure are intended to mean at or near the range of numbers or degrees, taking into account inherent manufacturing and material tolerances. When one element is identified as “on” another element, the elements may be in direct contact or an intervening element may be disposed between the elements.

The size or thickness of the areas or parts shown in the accompanying drawings may be somewhat exaggerated for clarity and ease of description.

The present describes a CMP device that may manufacture integrated semiconductor devices with improved wafer polishing rate, uniform material removal rate MRR at the wafer edge region, global thickness uniformity, and process efficiency by predicting the wear profile of the retainer ring and may improve the wear profile of the retainer ring during the CMP process.

A method of control of a CMP device having with improved wafer polishing rate, uniform material removal rate MRR at the wafer edge region, global thickness uniformity, and process efficiency by predicting the wear profile of the retainer ring and improving the wear profile of the retainer ring during the CMP process is described.

A method of modeling the wear profile of a retainer ring for a CMP process is described.

An apparatus for chemical mechanical polishing (CMP) of a wafer on which a semiconductor device is formed, according to an embodiment of the present disclosure, includes: a platen on which a polishing pad for the CMP process of the wafer is disposed on an upper surface; a head that rotates and vibrates the wafer on the polishing pad; a retainer ring disposed on an edge of the wafer to prevent the wafer from deviating from the head during the CMP process; and a control unit configured to calculate movement trajectory on the polishing pad of at least one reference point on a surface of the retainer ring in contact with the polishing pad and a center point of the retainer ring during the CMP process, calculate a sliding distance of the reference point and a trajectory distribution density of the center point, predicting a wear profile of the retainer ring from the sliding distance and the trajectory distribution density, and use the wear profile to control process conditions of the CMP.

In an embodiment, the control unit may establish a coordinate system that localizes a position on the polishing pad and calculates a movement trajectory in the coordinate system of the reference point of the retainer ring during a predetermined CMP process time, thereby calculating the sliding distance of the reference point. The coordinate system may be a Cartesian Coordinate System with the center of the polishing pad as an origin.

In an embodiment, the movement trajectories of the reference point and the center point may be calculated by sequentially applying one or more movement components due to a rotational speed of the head or the retainer ring, a movement component due to a vibration drive of the head or the retainer ring, and a movement component due to a rotational speed of the polishing pad.

In an embodiment, the control unit may establish a coordinate system that identifies a position on the polishing pad, identifies a center point between the reference point and opposite points located in opposite directions of the reference point with respect to the diameter of the retainer ring as the position of the retainer ring, and calculate a movement trajectory in the coordinate system of the center point during a predetermined CMP process time, and calculate a trajectory distribution density.

In an embodiment, the sliding distance and the travel trajectory distribution density may be calculated by parameterizing at least one of the rotational speed of the polishing pad, pressure of the head, rotational speed of the head and the retainer ring, frequency of the head and the retainer ring, vibration-driven movement form of the retainer ring, and vibration distance of the retainer ring. The CMP apparatus may include a user input unit for receiving the parameters from a user, and may receive from the user input values of one or more of the parameters: rotational speed of the polishing pad, pressure of the head, rotational speed of the head and the retainer ring, rotational speed of the head and the retainer ring, frequency of the head and the retainer ring, vibration-driven movement of the retainer ring, and vibration distance of the retainer ring.

In an embodiment, based on information received, the control unit may calculate the sliding distance of the reference point and the travel trajectory distribution density of the center point and build the wear profile of the retainer ring from the sliding distance and the travel trajectory distribution density.

In an embodiment, the control unit may modify one or more parameters to make the wear profile compatible with actual CMP process results: the rotational speed of the polishing pad applied to calculate the wear profile, the pressure of the head, the rotational speed of the head and the retainer ring, the frequency of the head and the retainer ring, the form of vibration-driven movement of the retainer ring, and the vibration distance of the retainer ring, or to improve the CMP process. The control unit may feedback the modified parameters to the CMP device to change the process conditions of the CMP.

In an embodiment, the control unit may determine a replacement interval for the retainer ring from the wear profile.

A method of controlling Chemical Mechanical Polishing (CMP) on a wafer on which a semiconductor device is formed according to an embodiment of the present disclosure includes: arranging a polishing pad for CMP process of a wafer on a platen, a head rotating and vibrating the wafer on the polishing pad, and a retainer ring arranged on an edge of the wafer to prevent the wafer from being dislodged from the head during the CMP process; calculating a movement trajectory on the polishing pad of at least one reference point on a surface of the retainer ring in contact with the polishing pad and a center point of the retainer ring during the CMP process, calculating a sliding distance of the reference point and a trajectory distribution density of the center point; predicting a wear profile of the retainer ring from the sliding distance and the trajectory distribution density; and using the wear profile to control process conditions of the CMP.

In an embodiment, calculating a sliding distance of the reference point and a distribution density of movement trajectories of the center point includes: establishing a coordinate system for locating a position on the polishing pad; calculating a movement trajectory in the coordinate system of the reference point of the retainer ring during a predetermined CMP process time, thereby calculating the sliding distance of the reference point; and identifying a center point between the reference point and opposite points located in opposite directions of the reference point, based on a diameter of the retainer ring, as a position of the retainer ring, and calculating a movement trajectory in the coordinate system of the center point during a predetermined CMP process time, thereby yielding a trajectory distribution density.

In an embodiment, the sliding distance and the travel trajectory distribution density may be calculated by parameterizing one or more of: rotational speed ω_{P} of the polishing pad, pressure of the head, rotational speed ω_{R} of the head and the retainer ring, frequency of the head and the retainer ring, shape of vibration-driven movement of the retainer ring, and vibration distance L of the retainer ring.

In an embodiment, controlling the process conditions of the CMP includes modifying one or more of: the rotational speed ω_{P} of the polishing pad applied to produce the wear profile, the pressure of the head, the rotational speed ω_{R} of the head and the retainer ring, the frequency of the head and the retainer ring, the form of vibration-driven movement of the retainer ring, and the vibration distance L of the retainer ring to make the parameters consistent with actual CMP process results or to improve the CMP process; and feeding the modified parameters back to the CMP device to change the process conditions of the CMP.

In an embodiment, a replacement interval for the retainer ring may be determined from the wear profile.

A method of modeling a wear profile of a retainer ring for a CMP process, according to an embodiment of the disclosure, may include: calculating a movement trajectory on the polishing pad of at least one reference point on a surface of the retainer ring in contact with a polishing pad during the CMP process and a center point of the retainer ring, calculating a sliding distance of the reference point and a trajectory distribution density of the center point on the polishing pad; and predicting a wear profile of the retainer ring from the sliding distance and the trajectory distribution density.

In an embodiment, calculating a sliding distance of the reference point and a distribution density of movement trajectories of the center point includes: establishing a coordinate system for locating a position on the polishing pad; calculating a movement trajectory in the coordinate system of the reference point of the retainer ring during a predetermined CMP process time, thereby calculating the sliding distance of the reference point; and identifying a center point between the reference point and opposite points located in opposite directions of the reference point, based on a diameter of the retainer ring, as a position of the retainer ring, and calculating a movement trajectory in the coordinate system of the center point during a predetermined CMP process time, thereby yielding the trajectory distribution density.

In an embodiment, the sliding distance and the travel trajectory distribution density may be calculated by parameterizing one or more of: rotational speed op of the polishing pad, pressure of the head, rotational speed ω_{R} of the head and the retainer ring, frequency of the head and the retainer ring, shape of vibration-driven movement of the retainer ring, and vibration distance L of the retainer ring.

According to an embodiment of the present disclosure, a CMP device may predict the wear profile of a retainer ring that extends beyond the diameter of the wafer and sets optimal process conditions based on this prediction, thereby maintaining the retainer ring in a desirable shape during the CMP process, thereby improving the wafer polishing rate as well as wafer edge thickness uniformity and extending the retainer ring replacement interval, thereby improving process efficiency and precision.

According to an embodiment of the present disclosure, a CMP apparatus may improve the efficiency and precision of the CMP process by using two vibration types, Latitudinal-Linearity Motion and Longitudinal-Arc Motion, and incorporating these two types of vibration into the predictive modeling of the wear profile of the retainer ring, and in particular, by analyzing the difference in wear distribution by vibration type, setting the optimal vibration conditions.

In accordance with an embodiment of the present disclosure, a CMP control method may accurately predict the wear profile of the retainer ring during the CMP process, thereby optimally maintaining the profile of the retainer ring during the CMP process, resulting in improved wafer polish rate, uniform material removal rate MRR at the wafer edge region, global thickness uniformity, and process efficiency.

According to an embodiment, a method of modeling a wear profile of a retainer ring for a CMP process may enable prediction of the wear profile of the retainer ring during the CMP process.

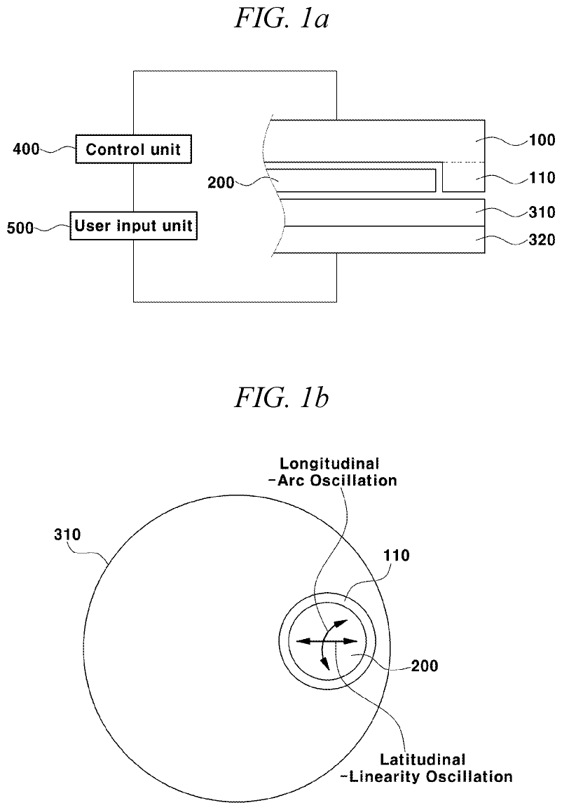

FIG. 1A illustrates a CMP apparatus according to an embodiment of the present disclosure, and FIG. 1B illustrates the movement of the retainer ring 110, a wafer 200, and a polishing pad 310 during the CMP process.

Referring to FIG. 1A and FIG. 1B, a CMP apparatus according to an embodiment of the present disclosure includes a platen 320, a polishing pad 310 disposed on the platen 320, a head 100 that rotates and vibrates a wafer 200 during polishing, a retainer ring 110 disposed on an edge of the wafer 200, a control unit 400, and a user input unit 500.

The platen 320 polishes the surface of the wafer 200 on which the epitaxial layer is formed by rotational motion at an angular velocity ω_{P} with the polishing pad 310 disposed on top. The head 100 vacuum adsorbs the wafer 200 undergoing polishing and moves the wafter to a predetermined position on the polishing pad 310, and during the CMP process, applies pressure to the wafer 200 disposed between the polishing pad 310 disposed on the platen 320 and the head 100 while rotating the wafer 200 at an angular velocity ω_{R} to rotate the wafer 200 and, optionally, to oscillate the wafer 200.

An abrasive, for example, a liquid slurry, is supplied to a predetermined area on the top of the polishing pad 310 to apply the slurry by rotating centrifugal force, while the wafer 200, which is held by the wafer carrier, the head 100, on the top of the polishing pad 310, is pressed against the surface of the polishing pad 310 to rotate and, optionally, oscillate at an angular velocity OR, such that the surface of the wafer 200 is leveled by the frictional effect of the polishing pad 310 and liquid slurry. In an embodiment, the vibration of the retainer ring 110 caused by the vibration of the head 100 may have a Latitudinal-Linearity Oscillation type or a Longitudinal-Arc type, as indicated by the arrows.

The CMP process polishes the surface of the wafer 200 by rotation and, optionally, vibration using the slurry as well as the polishing pad 310 disposed on the platen 320 and the head 100. In this example, the rotational speed ω_{P} of the polishing pad 310 by rotation of the platen 320, the pressure of the head 100, the rotational speed ω_{R} of the head 100 or the retainer ring 110, the frequency of the head 100 or the retainer ring 110, the form of vibration-driven movement of the retainer ring 110, for example, a latitudinal linear vibration type or a longitudinal arc vibration type, and the kinetic parameters of the CMP process, including the vibration distance L of the retainer ring 110, are parameters that establish a wear profile prediction model of the retainer ring 110. The parameters may be modified to improve the CMP process based on the analysis results of the wear profile prediction model, and the modified parameters are fed back to the CMP device to function as process conditions of the improved CMP process, and the control unit 400 performs the CMP process according to the process conditions.

During the CMP process, the change in the wear profile of the polishing pad 310 changes the contact angle of the polishing pad 310 and the retainer ring 110, which affects the polishing rate of the wafer edge region and thereby the global thickness uniformity, yield, and quality of the semiconductor device. In an embodiment of the present disclosure, the mechanical parameters that establish a wear profile prediction model of the retainer ring 110 is used to compare the predicted wear profile obtained from the wear profile prediction model with the actual measured wear profile and the polishing rate of the wafer edge region and the global thickness uniformity, yield, and semiconductor device quality with respect to at least one of the actual measured wear profile and wafers edge region polishing rate and global thickness uniformity, is modified for consistency with the actual CMP process results or modified to improve the CMP process, and the modified parameters are automatically and/or real-time fed back to the CMP device to function as process conditions for the improved CMP process. For example, by predicting the wear profile of the retainer ring 110 due to rotation and vibration of the retainer ring 110 during the CMP process, such as a convex pattern where the outer diameter of the retainer ring 110 is overworn or a concave pattern where the inner diameter of the retainer ring 110 is overworn, and predicting the resulting wafer edge thickness change, process parameters that improve the wear profile of the retainer ring 110 are derived, process conditions for the improved CMP are derived, and the CMP process is controlled. The control of the CMP process may be performed in real time or automatically.

As described, the parameters that determine the surface wear profile of the retainer ring 110 in the CMP process include the rotational speed Op of the polishing pad 310, the pressure of the head 100, the rotational speed ω_{R} of the head 100 and the retainer ring 110, the frequency of the head 100 and the retainer ring 110, one or more of the dynamic parameters of the CMP process, including, but not limited to, the type of vibration-driven movement of the retainer ring 110, for example, a latitudinal linear vibration type or a longitudinal arc vibration type, and the vibration distance L of the retainer ring 110. By using these parameters to predict the wear profile of the retainer ring 110, and managing the wear profile of the retainer ring 110 during the CMP process, a CMP device and method of control of the CMP device form complex, highly integrated semiconductor devices by improving the CMP process, such as the polishing rate of the wafer edge region and the resulting global thickness uniformity, yield, and quality of the semiconductor device.

In an embodiment of the present disclosure, improvement is accomplished by the control unit 400 calculating a movement trajectory on the polishing pad 310 of one or more predetermined fiducial points on a surface of the retainer ring 110 in contact with the polishing pad 310 during the CMP process and a center point of the retainer ring 110, calculating a sliding distance of the reference point and a movement trajectory distribution density of the center point, predicting a wear profile of the retainer ring 110 from the sliding distance and the movement trajectory distribution density, and modifying process conditions of the CMP and controlling the process of the CMP from the results of the predicted wear profile.

In an embodiment, the control unit 400 establishes a coordinate system for specifying a position on the polishing pad 310, for example, a Cartesian Coordinate System with the center of the polishing pad 310, which is circular, as an origin, and calculates a movement trajectory in the coordinate system of any position, referred to as a reference point, located on the retainer ring 110 during a predetermined process time, thereby calculating a sliding distance of the reference point. The control unit 400 identifies a center point between the reference point in the coordinate system and an opposite point located at 180°, in the opposite direction of the reference point, based on the diameter of the retainer ring 110, as a position of the retainer ring 110, and calculate a movement trajectory in the coordinate system of the center point during the process time, thereby calculating a distribution density of the movement trajectory of the retainer ring 110.

In an embodiment, the reference point and the movement trajectory of the center point are calculated by sequentially applying one or more of: a movement component due to rotational speed of the head 100 or retainer ring 110, a movement component due to vibration drive of the head 100 or retainer ring 110, and a movement component due to rotational speed of the polishing pad 310.

In an embodiment, a user input unit 500 receives the parameters from a user. The user may input any of the process parameters or any of the mechanical parameters via the user input unit 500, such as a predetermined identifier, for example, a make or model of the retainer ring and/or the CMP device, and the control unit 400 calculates, based on the inputted information, the sliding distance of the reference point and the travel trajectory distribution density of the center point, and build a predicted wear profile of the retainer ring, for example, a wear profile prediction model, from the sliding distance and the travel trajectory distribution density.

The control unit 400 utilizes the wear profile prediction model to predict the surface angle of the retainer ring 110 over a usage cycle to determine a replacement cycle or calibration cycle for the retainer ring 110. The control unit 400 utilizes the wear profile prediction model to determine a temperature for the CMP process. For example, the predicted surface angle between the retainer ring 110 and the polishing pad 310 is used to determine an improved contact angle, or the temperature of the CMP process is controlled taking into account that the retainer ring 110 wears faster as temperature increases.

The control unit 400 controls one or more values of the rotational speed of the head 100, the pressure of the head 100, the frequency, or the rotational speed of the polishing pad 310, or determines a form of vibration-driven movement of the retainer ring 110, for example, a type of vibration, using the wear profile prediction model. For example, the wear profile of the retainer ring 110 is predicted to ensure uniformity of the semiconductor wafer edge thickness, the rotational speed of the polishing pad 310 and the pressure of the head 100 are automatically determined, and the process conditions of the controlled CMP are not limited to these examples.

The control unit 400 uses the wear profile prediction model to analyze the effect of the vibration type of the retainer ring 110 on the wear distribution of the retainer ring 110 according to whether the vibration type is a latitudinal linear vibration type or a longitudinal arc vibration type, and after predicting the wear distribution according to each vibration type, select the most effective vibration type to extend the replacement cycle of the retainer ring 110 or improve the CMP process, such as the polishing rate of the wafer edge region and the resulting global thickness uniformity, yield, and quality of the semiconductor device.

For example, when the vibration type of the retainer ring 110 is a latitudinal linear vibration type, the contact area between the polishing pad 310 and the retainer ring 110 is relatively constant during the process, resulting in uniform wear, which may reduce or minimize the thickness deviation at the wafer edge, although localized wear is likely to occur at certain locations of the retainer ring 110, and the factory parameters are periodically adjusted. When the vibration type of the retainer ring 110 is a hardness arc vibration type, the wafer edge polishing effect may be amplified or maximized, although wear unevenness is likely to occur, and wear at specific locations may be compensated for by adjusting the vibration frequency and amplitude, such that the wear profile is predicted and the process conditions are adjusted to extend the service life of the retainer ring 110.

The type of vibration of the retainer ring 110 affects the change in the wear profile and the CMP process, and by taking the type of vibration into account, the wear profile for each type of movement may be predicted and the most effective type of vibration may be selected to improve the CMP process quality, such as global flattening of the wafer, while extending the lifetime of the retainer ring 110.

The present disclosure describes apparatus and method of improving the reliability of the CMP process and improving the accuracy of the wear profile prediction model by maintaining an optimal surface profile of the retainer ring 110 by comparing the predicted value using the wear profile prediction model with the actual measurement value. By applying the calibration algorithm based on the experimental data to the process condition control of the CMP, an automatic process improvement system may be established. According to an embodiment of the present disclosure, predicting the surface wear profile according to changes in process conditions, such as rotational speed of the polishing pad, rotational speed of the head or retainer ring 110, or vibration frequency of the retainer ring 110, or vibration type of the retainer ring 110, and applying improved values are possible, and by improving the surface wear of the retainer ring 110, pre-control of the hardenability of the retainer ring 110 may result.

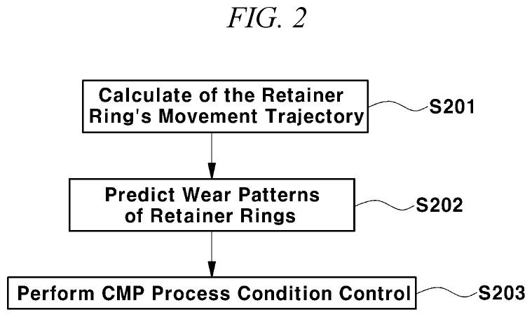

FIG. 2 is a flowchart illustrating a controlled method of chemical mechanical polishing of a wafer according to an embodiment of the present disclosure. The processes of the flowchart may be performed in a different order and may include fewer or additional processes than described and shown in FIG. 2.

Referring to FIG. 2, a method of control of CMP according to an embodiment of the present disclosure includes calculating S201 a movement trajectory on the polishing pad of at least one reference point on a surface of the retainer ring in contact with the polishing pad during a CMP process and a center point of the retainer ring, yielding a sliding distance of the reference point and a trajectory distribution density of the center point.

The control method of the CMP according to an embodiment of the present disclosure predicts S202 a wear profile of the retainer ring from the sliding distance and the travel trajectory distribution density.

In this example, a polishing pad that polishes the wafer is disposed on the upper surface of the platen, a head moves the wafer onto the platen, the head is disposed on the upper surface of the platen during the CMP process, and a retainer ring is disposed on the edge of the head to prevent the wafer from being dislodged from the head during the CMP process.

In an embodiment, the control method of the CMP establishes a coordinate system that specifies a position on the polishing pad, for example, an orthogonal coordinate system with an origin as the center of the polishing pad, which is circular, and calculates S201 a movement trajectory in the coordinate system for any reference point located on the retainer ring during a predetermined process time, thereby calculating the sliding distance of the reference point. The control method of the CMP identifies a center point between the reference point in the coordinate system and an opposite point located 180° in the opposite direction of the reference point relative to the diameter of the retainer ring, as a position of the retainer ring and calculates a movement trajectory of the center point in the coordinate system during the process time, thereby calculating a distribution density of the movement trajectory in the coordinate system of the retainer ring.

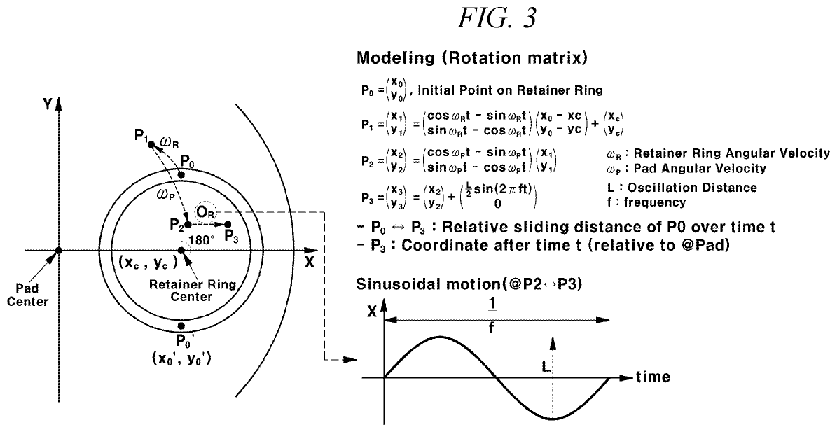

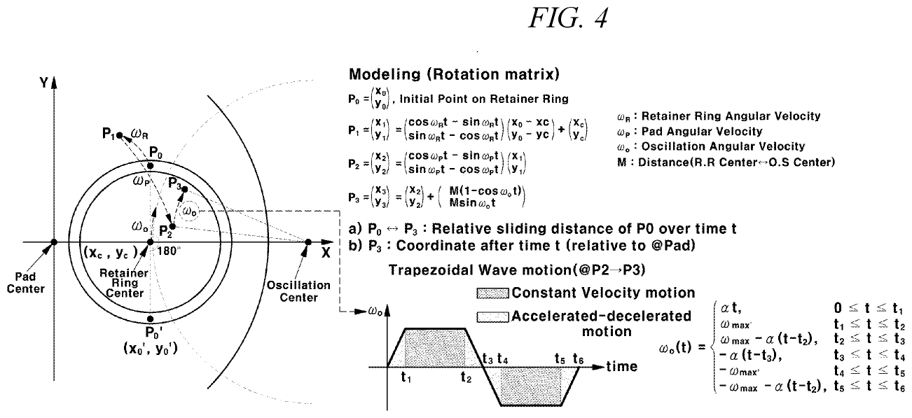

In an embodiment, the movement trajectory of the reference point and the center point is calculated by sequentially applying one or more of a movement component due to a rotational speed of the head or the retainer ring, a movement component due to a vibration drive of the head or the retainer ring, and a movement component due to a rotational speed of the polishing pad. In this example, a value of one or more of the rotational speed of the head or the retainer ring, the vibration of the head or the retainer ring and the rotational speed of the polishing pad are received from a user via a user input. A method for calculating a movement trajectory of the reference point and the center point of the retainer ring are described with reference to FIG. 3 and FIG. 4.

FIG. 3 illustrates movement trajectory of a reference point and a center point of a retainer ring with horizontal linear vibration in accordance with an embodiment of the present disclosure.

Referring to FIG. 3, in an embodiment of the present disclosure, a Cartesian coordinate system is established with the center of the polishing pad as the origin.

A trajectory is calculated in which a reference point P₀ on the retainer ring moves on the polishing pad according to the rotational transformation matrix as a function of process time and process parameters, such as the rotational speed op of the polishing pad, the rotational speed ω_{R} of the head or the retainer ring, the frequency f of the head, and the vibration distance L of the retainer ring. The reference point may be any point on the retainer ring and may be selected from an outer region, an inner region, and an intermediate region of the retainer ring depending on the position to be predicted. The reference point may include more than one point, depending on the embodiment, and is not limited to a specific location.

In an embodiment, the fiducial point P₀ on the retainer ring slides during a random process time t to a location at coordinate P₃, and the coordinate P₃ may be calculated by mathematical expressions. The coordinates (x₀, y₀) in the Cartesian coordinate system of the reference point P₀ on the retainer ring are moved to the coordinates (x₁, y₁) of the new position P₁ by the rotation of the head or the retainer ring. The coordinates (x₁, y₁) of the position P₁ are obtained as shown in Equation 1 using a rotation matrix that accounts for the rotation speed ω_{R} of the retainer ring.

$${P}_{1} = ( \begin{matrix}{x}_{1} \\ {y}_{1}\end{matrix} ) = ( \begin{matrix}cos {ω}_{R} t & - sin {ω}_{R} t \\ sin {ω}_{R} t & cos {ω}_{R} t\end{matrix} ) ( \begin{matrix}{x}_{0} - xc \\ {y}_{0} - yc\end{matrix} ) + ( \begin{matrix}{x}_{c} \\ {y}_{c}\end{matrix} ) \qquad Equation 1$$

In this example, the initial center coordinates in the Cartesian coordinate system of the retainer ring are (x_{c}, y_{c}).

The coordinates (x₁, y₁) of the position P₁ are moved to the coordinates (x₂, y₂) of the new position P₂ moved by the rotation of the polishing pad. The coordinates (x₂, y₂) of the position P₂ are obtained as shown in Equation 2 below by using the rotation matrix accounting for the rotation speed ω_{P} of the polishing pad.

$${P}_{2} = ( \begin{matrix}{x}_{2} \\ {y}_{2}\end{matrix} ) = ( \begin{matrix}cos {ω}_{p} t & - sin {ω}_{p} t \\ sin {ω}_{p} t & cos {ω}_{p} t\end{matrix} ) ( \begin{matrix}{x}_{1} \\ {y}_{1}\end{matrix} ) \qquad Equation 2$$

The coordinates (x₂, y₂) of the position P₂ are moved to the coordinates (x₃, y₃) of the new position P₃ by the latitudinal linear vibration drive of the head or retainer ring. The coordinates (x₃, y₃) of the position P₃ are obtained as shown in Equation 3 below using a sinusoidal wave function with the distance L traveled by the vibration and the vibration frequency f as variables.

$${P}_{3} = ( \begin{matrix}{x}_{3} \\ {y}_{3}\end{matrix} ) = ( \begin{matrix}{x}_{2} \\ {y}_{2}\end{matrix} ) + ( \begin{matrix}\frac{L}{2} sin ( 2 π f t ) \\ 0\end{matrix} ) \qquad Equation 3$$

A movement trajectory in the coordinate system of the reference point of the retainer ring is calculated, thereby yielding a sliding distance of the reference point. The center point between the reference point and opposite points located on the retainer ring and located in opposite directions of the reference point with respect to the diameter of the retainer ring are identified as the position of the retainer ring, and the trajectory of movement in the coordinate system of the center point during the process time is determined to calculate the trajectory distribution density of the retainer ring.

FIG. 4 illustrates movement trajectories of a reference point and a center point of a retainer ring undergoing longitudinal arc oscillation according to an embodiment of the present disclosure.

Referring to FIG. 4, in an embodiment, a Cartesian coordinate system is established with the pad center as the origin.

A reference point P₀ on the retainer ring is calculated according to the rotational transformation matrix to yield a trajectory that moves on the polishing pad at constant velocity motion and accelerated motion depending on the process time and process parameters, for example, the rotational speed of the polishing pad Op, the rotational speed of the head or retainer ring @R, and the vibration of the head. The reference point may be any point on the retainer ring. The reference point may include more than one point according to an embodiment and is not limited to this example.

In an embodiment, the reference point P₀ on the retainer ring slides during a random process time t to coordinate P₃, and the coordinate P₃ is calculated using mathematical expressions. The coordinates (x₀, y₀) in the Cartesian coordinate system of the reference point P₀ on the retainer ring are moved to the coordinates (x₁, y₁) of the new position P₁ by the rotation of the head or the retainer ring. The coordinates (x₁, y₁) of the position P₁ are obtained as shown in Equation 4 using a rotation matrix that accounts for the rotation speed ω_{R} of the retainer ring.

$${P}_{1} = ( \begin{matrix}{x}_{1} \\ {y}_{1}\end{matrix} ) = ( \begin{matrix}cos {ω}_{R} t & - sin {ω}_{R} t \\ sin {ω}_{R} t & cos {ω}_{R} t\end{matrix} ) ( \begin{matrix}{x}_{0} - xc \\ {y}_{0} - yc\end{matrix} ) + ( \begin{matrix}{x}_{c} \\ {y}_{c}\end{matrix} ) \qquad Equation 4$$

In this example, the initial center coordinates in the Cartesian coordinate system of the retainer ring are (x_{c}, y_{c}).

The coordinates (x₁, y₁) of the position P₁ are moved to the coordinates (x₂, y₂) of the new position P₂ moved by the rotation of the polishing pad. The coordinates (x₂, y₂) of the position P₂ are obtained as shown in Equation 5 using the rotation matrix accounting for the rotation speed ω_{P} of the polishing pad.

$${P}_{2} = ( \begin{matrix}{x}_{2} \\ {y}_{2}\end{matrix} ) = ( \begin{matrix}cos {ω}_{p} t & - sin {ω}_{p} t \\ sin {ω}_{p} t & cos {ω}_{p} t\end{matrix} ) ( \begin{matrix}{x}_{1} \\ {y}_{1}\end{matrix} ) \qquad Equation 5$$

The coordinates (x₂, y₂) of the position P₂ are moved to the coordinates (x₃, y₃) of a new position P₃, driven by the longitudinal arc oscillation of the head or retainer ring. The coordinates (x₃, y₃) of the position P₃ are obtained as shown in Equation 6 using a trapezoidal wave function with a constant velocity motion and accelerated motion interval depending on the vibration.

$${P}_{3} = ( \begin{matrix}{x}_{3} \\ {y}_{3}\end{matrix} ) = ( \begin{matrix}{x}_{2} \\ {y}_{2}\end{matrix} ) + ( \begin{matrix}M ( 1 - cos {ω}_{0} t ) \\ M sin {ω}_{0} t\end{matrix} ) \qquad Equation 6$$

In this example, M is a distance from the center point of the retainer ring to the center of vibration.

A movement trajectory in the coordinate system of the reference point of the retainer ring may be calculated, thereby yielding a sliding distance of the reference point. The center point between the reference point and opposite points located on the retainer ring and located in opposite directions of the reference point with respect to the diameter of the retainer ring may be identified as the position of the retainer ring, and the movement trajectory in the coordinate system of the center point during the process time is determined to calculate the trajectory distribution density of the retainer ring.

As described with reference to FIG. 1 to FIG. 4, the reference point and the center point have a movement trajectory calculated according to one or more of a rotational speed ω_{R} of the polishing pad, a rotational speed ω_{R} of the head or retainer ring, a form of movement by vibration drive of the retainer ring, a frequency f of the head, a vibration distance L of the retainer ring, a distance M from a center point of the retainer ring to a center of vibration, and process parameters entered by the user.

In accordance with an embodiment, a predetermined identifier, for example, a make or model of the retainer ring and/or the CMP device, is assigned to a predetermined process parameter, for example, a latitudinal linear vibration type or a longitudinal arc vibration type of the head 100 or the retainer ring 110. After calculating S201 a sliding distance of the reference point and a trajectory distribution density of the center point using process parameters corresponding to the identifier when the identifier is entered in the user interface, the CMP device generates a wear profile prediction model that predicts S202 a wear profile of the retainer ring from the sliding distance and the trajectory distribution density.

A wear profile prediction model according to the present disclosure is described. The Material Removal Rate MRR is represented by the Preston equation as shown in Equation 7 in an embodiment. The Material Removal Rate MRR is not limited to Equation 7, and in an embodiment, a modified Preston equation is applied, or various other equations based on particle and slurry characteristics and hydrodynamics during the CMP process, with CMP process variables, such as pressure or chemical properties, as parameters.

$$M R R = {C}_{P} * P * V \qquad Equation 7$$

Cₚ is Preston's constant, which may be determined from various variables related to the CMP process. P represents pressure and V represents the relative velocity between the polishing pad and the retainer ring.

From the material etch rate, the amount of material MRRdt removed during unit time dt is expressed in Equation 8.

$$MRRdt = {C}_{P} * P * V * d t \qquad Equation 8$$

The material etch rate of the substrate during the process time t is expressed in Equation 9.

$$M R {R}_{t} = {C}_{P} * P * {\int }_{0}^{t} V d t = P * {C}_{P} * {S}_{t} \qquad Equation 9$$

where Sₜ is the sliding distance of a predetermined reference point on the retainer ring during the CMP process time t.

The sliding distance Sₜ is calculated from the movement trajectory of a predetermined reference point of the retainer ring. In an embodiment, the inner pressure Pᵢₙₙₑᵣ and the outer pressure Pₒᵤₜₑᵣ of the retainer ring are the same during the CMP process to compare the removal rate between the inner diameter and the outer diameter of the retainer ring.

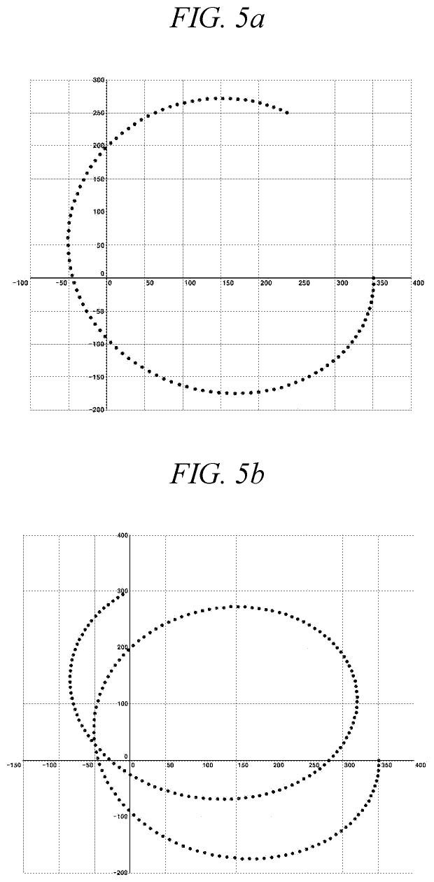

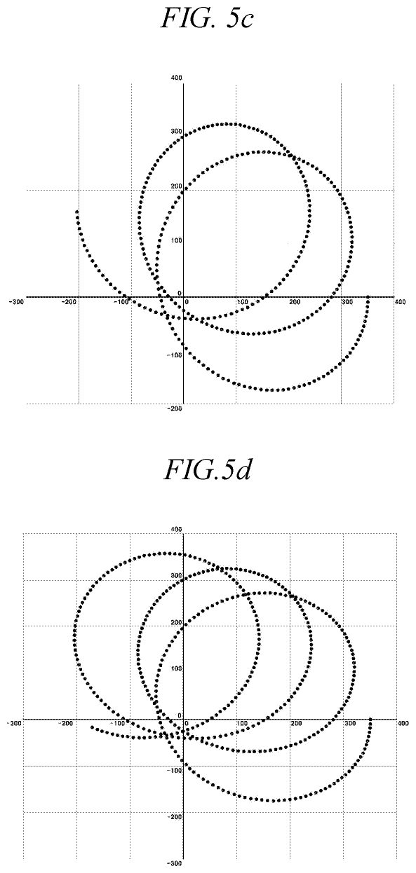

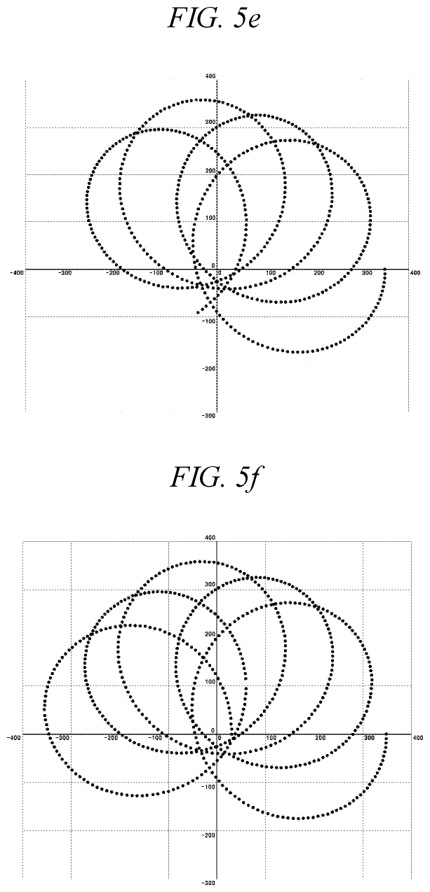

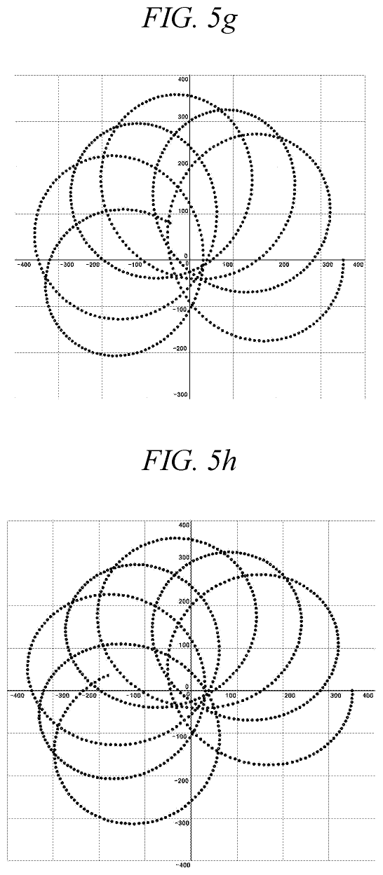

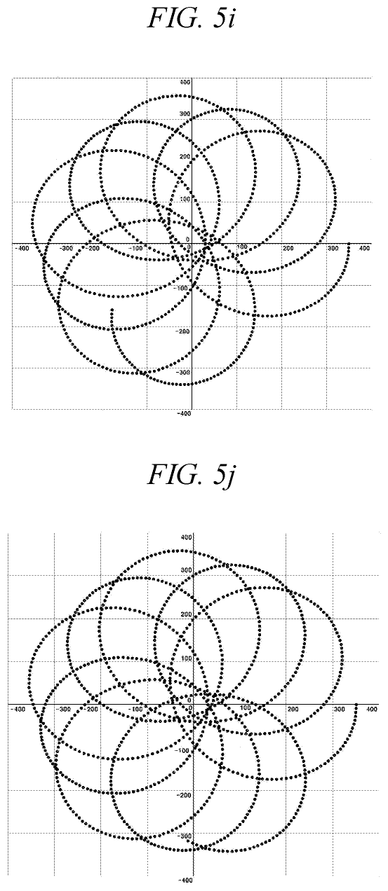

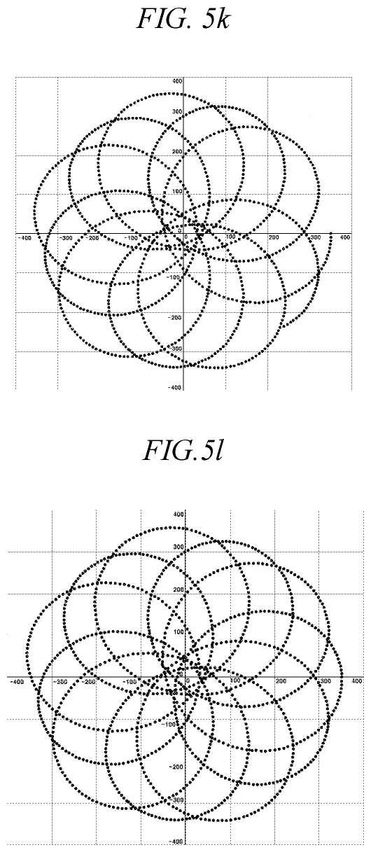

FIG. 5a to FIG. 51 show the calculated result of the movement trajectory of the retainer ring over time of a CMP process according to an embodiment of the present disclosure.

Referring to FIG. 5a to FIG. 51, when the rotation speed of the polishing pad is set to 50 RPM, the rotation speed of the head is 55 RPM, and the vibration-driven movement of the retainer ring is a sine wave in the form of a latitudinal linear form, the movement trajectory of a predetermined reference point of the retainer ring in the Cartesian coordinates with the center point of the polishing pad as the origin for 12 seconds is shown in sequence as 12 drawings at 1-second intervals.

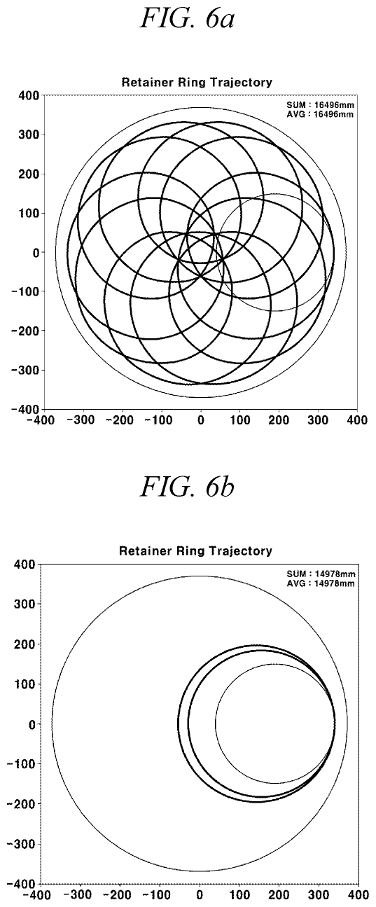

FIG. 6 a and FIG. 6b illustrate the movement trajectory of a predetermined reference point of the retainer ring, for different rotational speed ratios of the polishing pad and the head of the CMP process, according to an embodiment of the present disclosure. The vibration type of the retainer ring has a latitudinal linear vibration type in this example.

Referring to FIG. 6a and FIG. 6b, FIG. 6a shows a line illustrating a movement trajectory of a predetermined reference point of the retainer ring when the ratio of the rotational speed of the polishing pad, and the rotational speed of the head, identified as (the rotational speed of the polishing pad)/(the rotational speed of the head or the retainer ring), is not equal to one, such as 50 RPM/55 RPM, which is about 0.91. FIG. 6b shows a line illustrating a movement trajectory of a predetermined reference point of the retainer ring when the ratio of the rotational speed of the polishing pad and the head is equal to one, such as 50 RPM/50 RPM. Unlike FIG. 6a, FIG. 6b only shows the movement trajectory of the retainer ring due to the vibration of the retainer ring, which vibration has the disadvantage of causing localized wear of the polishing pad.

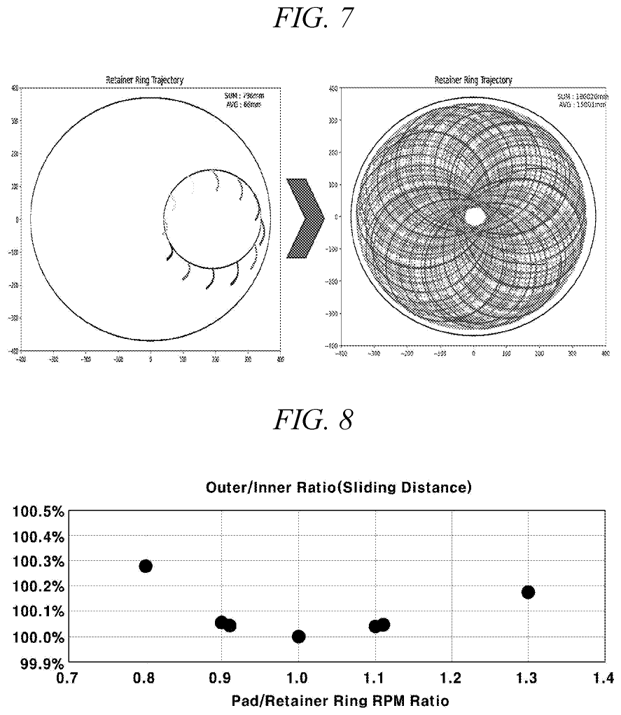

FIG. 7 illustrates movement trajectories of a plurality of reference points on a retainer ring in accordance with an embodiment of the present disclosure.

Referring to FIG. 7, when the rotation speed of the polishing pad is set to 50 RPM and the head to 55 RPM, the vibration-driven movement of the retainer ring is a longitudinal arc, and 12 reference points are designated as reference points at 30° intervals as shown in the drawing on the left, and the movement trajectories of the 12 reference points, coded are shown in the drawing on the right.

FIG. 8 shows results of calculations of the ratio of the sliding distance of the outer region and the inner region of the retainer ring according to various rotational speed ratios of the polishing pad and the head of the CMP device according to an embodiment of the present disclosure. The movement trajectory during the CMP process is calculated for a predetermined first reference point selected in the outer region of the retainer ring and a predetermined second reference point selected in the inner region, and the sliding distance Sₜ between the first reference point and the second reference point is derived. The vibration type of the retainer ring is a latitudinal linear vibration type in this example.

Referring to FIG. 8, when the rotational speed ratio of the polishing pad and the head is 1, the sliding distance ratio of the first reference point and the second reference point is equal to 100%. When the rotational speed ratio of the polishing pad and the head is less than 1 or greater than 1, the sliding distance ratio of the first reference point and the second reference point exceeds 100%, indicating that the outer region of the retainer ring in which the first reference point is located has a larger sliding distance than the inner region of the retainer ring in which the second reference point is located, and the outer region of the retainer ring wear smore than the inner region during the CMP process.

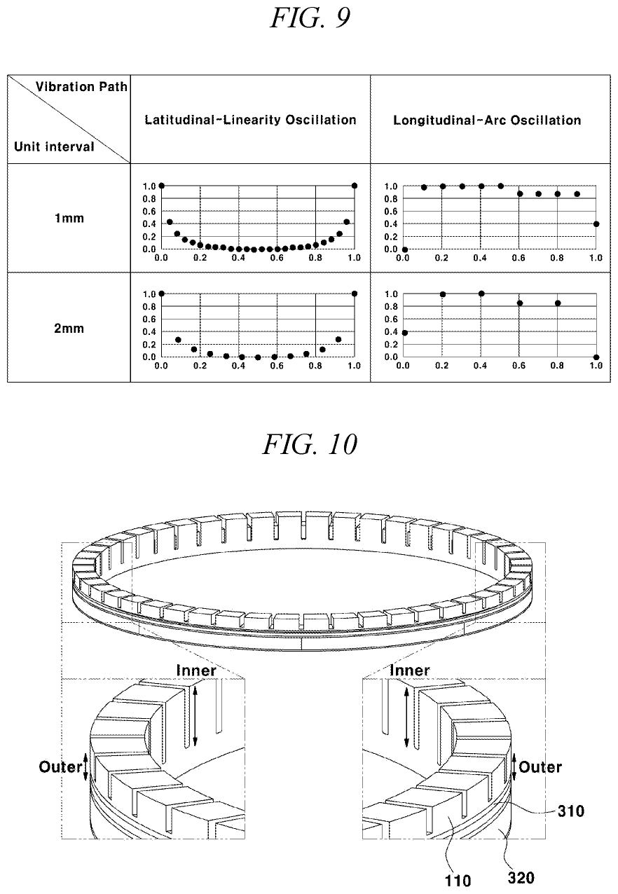

FIG. 9 illustrates a distribution of the movement trajectory of the retainer ring according to two types of vibration of the retainer ring according to an embodiment of the present disclosure. The results of counting the frequency, y-axis, of the center point of the retainer ring by position on the polishing pad, x-axis, from the trajectory of the center point of the retainer ring by setting the unit spacing in the radial direction from the center of the polishing pad to 1 mm and 2 mm, are shown normalized.

Referring to FIG. 9, when the vibration path of the retainer ring has a latitudinal linear vibration, the vibration path has a concave curve shape distribution as shown in the left-side plot, and when the vibration path of the retainer ring has a longitudinal arc vibration, the vibration path has a convex curve shape distribution as shown in the right-side plot. Based on these results, depending on the vibration path of the retainer ring, the wear profile of the retainer ring is predicted as different and the polishing efficiency Cₚ is different. For example, when the vibration-driven movement form or vibration path of the retainer ring is a latitudinal linear vibration, the retainer ring's trajectory frequency increases toward the center and edge of the polishing pad, and the outer region of the retainer ring tends to wear more than the inner region. When the vibration path of the retainer ring is a longitudinal arc vibration, the frequency of the retainer ring's trajectory toward the center and edges of the polishing pad tends to decrease relative to other areas, resulting in greater wear on the inner areas of the retainer ring than on the outer areas.

The wear prediction model of the retainer ring according to an embodiment of the present disclosure may improve the CMP process by predicting the wear distribution of the retainer ring along the vibration path of the retainer ring, taking into account the qualitative and quantitative dependence of the wear profile of the retainer ring on the vibration path of the retainer ring, and selecting the most effective type of vibration.

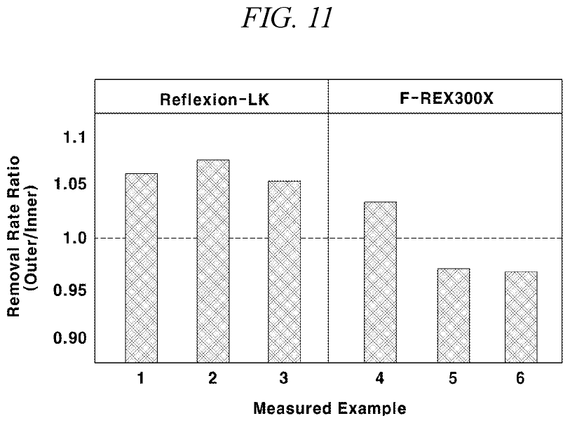

FIG. 10 shows the measurement locations of the outer thickness and the inner thickness of the retainer ring to evaluate conformity of the simulation results of the wear profile prediction of the retainer ring according to an embodiment of the present disclosure with the actual experimental values, and FIG. 11 is a graph showing the measured results of the wear ratio of the outer and inner sides of the retainer ring according to the vibration path of the retainer ring by the actual CMP process.

The process conditions of the actual CMP process for the simulation of the wear profile prediction and the evaluation of conformity are shown in Table 1. In Table 1, the hardware model is the CMP process device used to validate the wear profile prediction simulation results, Reflexion-LK is commercially available from Applied Material, California, USA, and F-REX300X is commercially available from EBARA, Tokyo, Japan.

TABLE 1

| Simulation/Process | | | | | | |
|---|---|---|---|---|---|---|
| Conditions | Example 1 | Example 2 | Example 3 | Example 4 | Example 5 | Example 6 |
| Hardware model | Reflexion-LK | Reflexion-LK | Reflexion-LK | F-REX300X | F-REX300X | F-REX300X |
| Vibration type | Latitude | Latitude | Latitude | No vibration | Longitudinal | Longitudinal |
| | Linear | Linear | Linear | | arc vibration | arc vibration |
| | Oscillation | Oscillation | Oscillation | | | |
| Rotational speed | 0.99 | 1.01 | 1.06 | 0.99 | 0.99 | 1.06 |
| ratio of the | | | | | | |
| pad/retainer ring | | | | | | |
| Rotation direction | Counter | Counter | Counter | Counter | Counter | Counter |
| of the pad | clockwise | clockwise | clockwise | clockwise | clockwise | clockwise |
| Retainer | Counter | Counter | Counter | Counter | Counter | Counter |
| RingForward | clockwise | clockwise | clockwise | clockwise | clockwise | clockwise |
| Process time (hr) | 300 | 150 | 100 | 200 | 100 | 300 |

The results of the evaluation of the conformity between the simulation results of the predicted wear profiles of the retainer rings of the experimental examples according to the simulation/process conditions in Table 1 and the measured values of the actual CMP process are shown in Table 2. The measured values of the wear ratio of the outer surface and the inner surface of the retainer ring in the actual CMP process are shown in FIG. 11.

TABLE 2

| Simulation/ | | Simulation prediction results | | |
|---|---|---|---|---|
| Process | | Polishing | Sliding | Experiment |
| Conditions | Vibration type | Efficiency Cp | Distance St | results |
| Example 1 | Latitude Linear | Outer Wear ↑ | Outer Wear ↑ | Outer Wear ↑ |
| | Oscillation | | | |
| Example 2 | Latitude Linear | Outer Wear ↑ | Outer Wear ↑ | Outer Wear ↑ |
| | Oscillation | | | |
| Example 3 | Latitude Linear | Outer Wear ↑ | Outer Wear ↑ | Outer Wear ↑ |
| | Oscillation | | | |
| Example 4 | No vibration | X | Outer Wear ↑ | Outer Wear ↑ |
| Example 5 | Longitudinal arc | Medial wear ↑ | Outer Wear ↑ | Medial wear ↑ |
| | vibration | | | |
| Example 6 | Longitudinal arc | Medial wear ↑ | Outer Wear ↑ | Medial wear ↑ |
| | vibration | | | |

Referring to Table 2, from the actual CMP process results or experimental results of the retainer rings for Examples 1 to 6, the wear profile of the retainer ring depends on the type of vibration of the retainer ring, and, generally, the inner wear of the retainer ring is increased over the outer wear of the retainer ring when the retainer ring has a latitudinal linear vibration type, and the inner wear of the retainer ring is increased over the outer wear of the retainer ring when the retainer ring has a longitudinal arc vibration type. For example, Example 5 and Example 6 compared to Example 4 show the wear profile of the retainer ring is highly dependent on the type of vibration of the retainer ring.

As shown in Example 4, in the absence of oscillatory movement of the retainer ring during the CMP process, the sliding distance Sₜ predicted by the simulation is larger in the outer region compared to the inner region of the retainer ring, which is consistent with the results obtained from the actual CMP process, where the outer region has a relatively larger wear rate. In Example 5 and Example 6, the wear profile of the retainer ring by the actual CMP process has stronger dependence on the predicted polishing efficiency Cₚ than on the sliding distance Sₜ. The abrasive efficiency Cₚ is related to the temperature during the CMP process and the type of vibration of the retainer ring, where the temperature varies with the position of the retainer ring and the type of vibration of the retainer ring is considered to reflect the distribution of the abrasive efficiency Cₚ with the position of the retainer ring.

According to an embodiment of the present disclosure, the sliding distance of a reference point of the retainer ring and the trajectory distribution of the retainer ring as the retainer ring moves on the polishing pad are quantified to more accurately predict the wear profile of the retainer ring as the wear profile appears in an actual CMP process. According to an embodiment of the present disclosure, how the type of vibration of the retainer ring affects the wear profile of the retainer ring may be interpreted.

Referring to FIG. 2, after predicting S202 a wear profile of the retainer ring from the sliding distance and the movement trajectory distribution density, the predicted wear profile, for example, a wear profile prediction model, is used to control S203 the process conditions of the CMP.

The process conditions of the controlled CMP may be set in various ways, for example, the wear profile of the retainer ring affects the polishing uniformity of the wafer, such that the control unit utilizes the wear profile prediction model to adjust the inward or outward load on the surface of the retainer ring and adjust the surface angle of the ring being worn, for example, the rotational speed of the polishing pad, the pressure of the head, the rotational speed of the head or the retainer ring, the frequency of the head or the retainer ring, the form of movement by the vibration drive, for example, the latitudinal linear vibration type, the longitudinal arc type, and the vibration distance of the retainer ring, the frequency of the head or the retainer ring, the form of the vibration-driven movement of the retainer ring, for example, a latitudinal linear vibration type or a longitudinal arc vibration type, and the vibration distance of the retainer ring, such that performance of the CMP process may be improved by controlling one or more of the values of the dynamic parameters of the CMP process, including, but not limited to, controlling the process conditions.

According to an embodiment of the present disclosure, a CMP apparatus and a method of control of the apparatus may improve a CMP process that forms complex highly integrated semiconductor devices by more accurately predicting the wear profile of a retainer ring and setting process conditions based on on the predictions, thereby maintaining the retainer ring in a desirable geometry during the CMP process, improving wafer polishing rate, uniform material removal rate MRR at wafer edge regions, global thickness uniformity, and process efficiency of CMP.

According to an embodiment of the present disclosure, the form of vibration-driven movement of the retainer ring 110, for example, two types of vibration, for example, a latitudinal linear vibration type and a longitudinal arc vibration type, and a wear profile prediction model of the retainer ring may be built considering the two types of vibration, and for example, the difference in the wear distribution of the retainer ring by the type of vibration may be analyzed to set improved vibration conditions, thereby improving the CMP process.

In an embodiment of the present disclosure, the parameters reflect temperature variations and contact zone characteristics of the retainer ring and may provide a CMP apparatus and control method capable of generating the wear profile prediction model, thereby more accurately predicting the wear profile of the retainer ring and improving the process conditions of the CMP automatically and/or in real time.

According to an embodiment of the present disclosure, the wear profile of the retainer ring due to changes in the CMP process conditions may be predicted to improve the surface wear of the retainer ring, thereby proactively controlling the hardenability of the retainer ring.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A chemical mechanical polishing (CMP) device for a wafer from which semiconductor devices are formed, the CMP device comprising:
a platen and a polishing pad disposed on a first surface of the platen in a configuration that performs a CMP process on a wafer;
a head that rotates and vibrates the wafer on the polishing pad;
a retainer ring disposed at an edge of the polishing pad and configured to prevent the wafer from dislodging from the head during the CMP process; and
a control unit configured to:
calculate a movement trajectory on the polishing pad of at least one reference point on a surface of the retainer ring in contact with the polishing pad and a center point of the retainer ring during the CMP process;
calculate a sliding distance of the at least one reference point and a trajectory distribution density of the movement trajectory of the center point;
predict a wear profile of the retainer ring based on the sliding distance and the trajectory distribution density; and
control process conditions of the CMP process based on the wear profile.

2. The device of claim 1, wherein the control unit is configured to calculate, during a predetermined CMP process time, the movement trajectory of the reference point to calculate the sliding distance of the reference point.

3. The device of claim 2, wherein the movement trajectory of the reference point is determined using an origin at a center of the polishing pad.

4. The device of claim 1, wherein the movement trajectory of the reference point and the center point is calculated by sequentially applying at least one of a movement components selected from:
a movement component caused by a rotational speed of the head or the retainer ring,
a movement component caused by vibrational driving of the head or the retainer ring, and
a movement component caused by a rotational speed of the polishing pad.

5. The device of claim 1, wherein the control unit is configured to:
identify, as a position of the retainer ring, a midpoint between the reference point and an opposing point located opposite to the reference point with respect to a diameter of the retainer ring; and
calculate, during a predetermined CMP process time, the movement trajectory of the midpoint to calculate the trajectory distribution density.

6. The device of claim 1, wherein the sliding distance and the travel trajectory distribution density are calculated based on at least one of the parameters: rotational speed of the polishing pad, pressure of the head, rotational speed of the head and the retainer ring, frequency of the head and the retainer ring, form of vibration-driven movement of the retainer ring, and vibration distance of the retainer ring.

7. The device of claim 6, further comprising:
a user input unit configured to receive the parameters from the user; and
wherein the user input unit is configured to receive process parameters corresponding to a manufacturer or model of the retainer ring or the CMP apparatus, or at least one parameter selected from the rotational speed of the polishing pad, the pressure of the head, the rotational speed of the head and/or the retainer ring, the vibration frequency of the head and/or the retainer ring, a movement pattern caused by vibrational driving of the retainer ring, and the vibration distance of the retainer ring; and
wherein the control unit is configured to calculate the sliding distance and the trajectory distribution density based on the received information and to construct the wear profile of the retainer ring based on the sliding distance and the trajectory distribution density.

8. The device of claim 1, wherein the control unit is configured to modify one or more parameters selected from the rotational speed of the polishing pad applied to produce the wear profile, the pressure of the head, the rotational speed of the head and the retainer ring, the frequency of the head and the retainer ring, the form of vibration-driven movement of the retainer ring, and the vibration distance of the retainer ring, and to feed back the modified parameters to the CMP apparatus to change process conditions of the CMP process.

9. The device of claim 1, wherein the control unit is configured to determine a replacement cycle of the retainer ring based on the wear profile.

10. A method of controlling a chemical mechanical polishing (CMP) process that polishes a wafer from which semiconductor devices are formed, the method comprising:
using a head, rotating and vibrating the wafer on a polishing pad disposed on a first surface of a platen while a retainer ring disposed at an edge of the wafer prevents separation of the wafer from the head during the CMP process;
calculating, during the CMP process, a movement trajectory on the polishing pad of at least one reference point on a surface of the retainer ring contacting the polishing pad and a center point of the retainer ring, and calculating a sliding distance of the reference point and a trajectory distribution density of the movement trajectory of the center point;
predicting a wear profile of the retainer ring based on the sliding distance and the trajectory distribution density; and
controlling process conditions of the CMP process based on the wear profile.

11. The method of claim 10, wherein calculating the sliding distance and the trajectory distribution density comprises:
calculating, during a predetermined CMP process time, the movement trajectory of the reference point to calculate the sliding distance; and
identifying, as a position of the retainer ring, a midpoint between the reference point and point located opposite to the reference point with respect to a diameter of the retainer ring, and calculating, during the predetermined CMP process time, the movement trajectory of the midpoint to calculate the trajectory distribution density.

12. The method of claim 10, wherein the sliding distance and the trajectory distribution density are calculated based on at least one of the parameters: rotational speed of the polishing pad, pressure of the head, rotational speed of the head and the retainer ring, frequency of the head and the retainer ring, vibration-driven movement of the retainer ring, and vibration distance of the retainer ring.

13. The method of claim 10, wherein controlling the process comprises:
modifying one or more parameters selected from the rotational speed of the polishing pad, the pressure of the head, the rotational speed of the head and/or the retainer ring, the vibration frequency of the head and/or the retainer ring, a movement pattern caused by vibrational driving of the retainer ring, and the vibration distance of the retainer ring to correspond to actual CMP process results; and
feeding back the modified parameters to the CMP apparatus to change the process conditions.

14. The method of claim 10, further comprising determining a replacement cycle of the retainer ring based on the wear profile.

15. A method of modeling a wear profile of a retainer ring for a CMP process, the method comprising:
calculating, during a CMP process, a movement trajectory on a polishing pad of at least one reference point on a surface of the retainer ring contacting the polishing pad and a center point of the retainer ring and calculating a sliding distance of the reference point and a trajectory distribution density of the movement trajectory of the center point; and
predicting a wear profile of the retainer ring based on the sliding distance and the trajectory distribution density.

16. The method of claim 15, wherein calculating the sliding distance and the trajectory distribution density comprises:
calculating, during a predetermined CMP process time, the movement trajectory of the reference point to calculate the sliding distance; and
identifying, as a position of the retainer ring, a midpoint between the reference point and a point located opposite to the reference point with respect to a diameter of the retainer ring and calculating, during the predetermined CMP process time, the movement trajectory of the midpoint to calculate the trajectory distribution density.

17. The method of claim 15, wherein the sliding distance and the trajectory distribution density are calculated using one or more parameters from among:
a rotational speed of the polishing pad,
a pressure of a head,
a rotational speed of the head and the retainer ring,
a vibration frequency of the head and the retainer ring,
a movement pattern caused by vibrational driving of the retainer ring, and
a vibration distance of the retainer ring.
